(19) United States
(12) Patent Application Publication
(10) Pub. No.: US 2017/0294395 A1
(43) Pub. Date: Oct. 12, 2017

(54) SEMICONDUCTOR DEVICE THAT INCLUDES A MOLECULAR BONDING LAYER FOR BONDING ELEMENTS

(71) Applicant: KABUSHIKI KAISHA TOSHIBA, Tokyo (JP)

(72) Inventor: Akihiko HAPPOYA, Ome Tokyo (JP)

(21) Appl. No.: 15/442,263

(22) Filed: Feb. 24, 2017

Related U.S. Application Data
(60) Provisional application No. 62/319,670, filed on Apr. 7, 2016.
(60) Provisional application No. 62/382,031, filed on Aug. 31, 2016.

(51) Int. Cl. H01L 23/00; H01L 23/495

(52) U.S. Cl. CPC H01L 24/29; H01L 24/33; H01L 24/04; H01L 23/49582; H01L 23/49586; H01L 23/49513; H01L 24/83; H01L 2224/04026; H01L 2224/29193; H01L 2224/33505; H01L 2224/32245; H01L 2224/83851; H01L 2224/83894

(57) ABSTRACT

A semiconductor device includes a base, a semiconductor chip on the base, a conductive bonding layer between a surface of the base and a surface of the semiconductor chip, the conductive bonding layer including a resin and a plurality of conductive particles contained in the resin, and a molecular bonding layer between the surface of the semiconductor chip and a surface of the conductive bonding layer, and including a molecular portion covalently bonded to a material of the semiconductor chip and a material of the conductive bonding layer.

### CROSS-REFERENCE TO RELATED APPLICATIONS

This application is based upon and claims the benefit of priority from U.S. Provisional Patent Application No. 62/319,670, filed on Apr. 7, 2016, and U.S. Provisional Patent Application No. 62/382,031, filed on Aug. 31, 2016, the entire contents of all of which are incorporated herein by reference.

### FIELD

Embodiments described herein relate generally to a semiconductor device and a method of manufacturing the semiconductor device.

### BACKGROUND

Semiconductor devices including a die bonding adhesive layer are known.

### BRIEF DESCRIPTION OF THE DRAWINGS

FIG. 1 is a perspective view of an electronic device including a semiconductor device according to a first embodiment.

FIG. 2 is a cross-sectional view of the semiconductor device according to the first embodiment.

FIG. 3 is an enlarged cross-sectional view of a vicinity of a semiconductor chip included in the semiconductor package shown in FIG. 2.

FIG. 4 is a schematic cross-sectional view of a part of the semiconductor device according to the first embodiment.

FIG. 5 schematically illustrates a composition of a molecular bonding layer in the semiconductor package according to the first embodiment.

FIG. 6 is a cross-sectional view of a structure in process to show a flow of a method of manufacturing the semiconductor device according to the first embodiment.

FIG. 7 is a perspective view of a bottom of a semiconductor chip according to a second embodiment.

FIG. 8 is an enlarged cross-sectional view of a vicinity of the semiconductor chip according to the second embodiment.

FIG. 9 is a cross-sectional view of a semiconductor device according to a third embodiment.

FIG. 10 is a cross-sectional view of a board unit according to a fourth embodiment.

FIG. 11 is a perspective view of a bottom of a semiconductor device according to the fourth embodiment.

### DETAILED DESCRIPTION

A semiconductor device according to an embodiment includes a base, a semiconductor chip on the base, a conductive bonding layer between a surface of the base and a surface of the semiconductor chip, the conductive bonding layer including a resin and a plurality of conductive particles contained in the resin, and a molecular bonding layer between the surface of the semiconductor chip and a surface of the conductive bonding layer, and including a molecular portion covalently bonded to a material of the semiconductor chip and a material of the conductive bonding layer.

A semiconductor device and a method of manufacturing the semiconductor device according to embodiments will be described below with reference to the drawings. In the following description, components having the same or similar functions are denoted by the same reference numerals and redundant descriptions thereof will be omitted. It is noted that the drawings are schematic and the numbers, thicknesses, widths, proportions, and the like of components may be different from those of actual components.

### First Embodiment

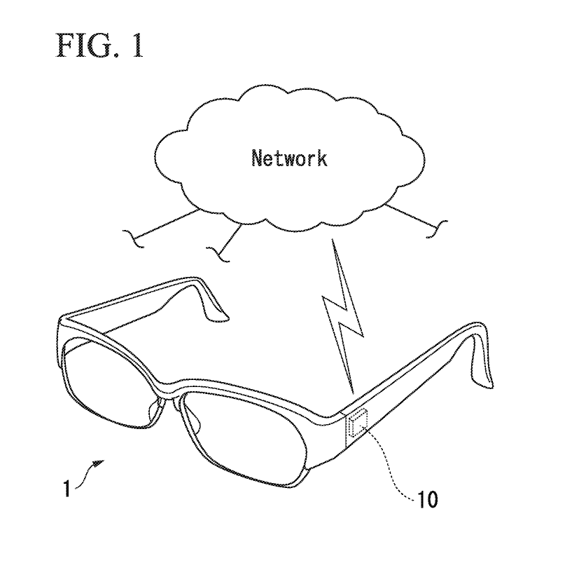

A first embodiment will be described with reference to FIG. 1 to FIG. 6.

FIG. 1 is a perspective view of an electronic device 1 according to the first embodiment. The electronic device 1 includes a semiconductor package (device) 10 according to the first embodiment. The electronic device 1 is, for example, a wearable device, but not limited thereto. The electronic device 1 is an electronic device according to, for example, Internet of Things (IoT), and can be connected to the Internet through a wireless or wired network. One example of the semiconductor package 10 includes a processor (e.g., a central processing unit), a sensor, and a wireless module. Also, the electronic device 1 and the semiconductor package 10 are not limited to the above example. The electronic device 1 may be an electronic device for a vehicle or electronic devices for other purposes. The semiconductor package 10 may be a semiconductor component that is used as a vehicle component or a power semiconductor, or may be a semiconductor component used for other purposes. In addition, a semiconductor package 10 and a board unit 90 according to second to fourth embodiments to be described below may be included in the electronic device 1.

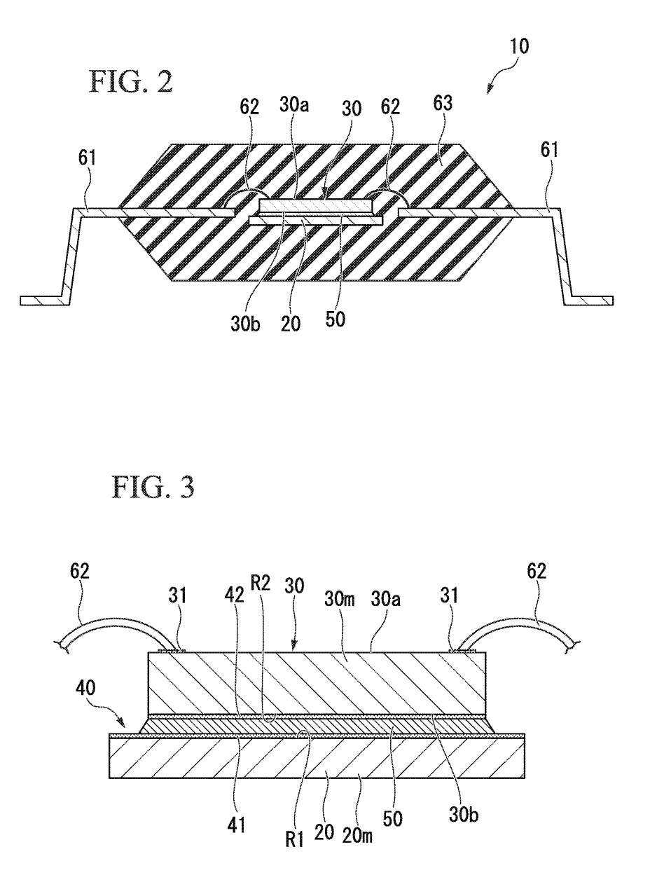

FIG. 2 is a cross-sectional view of the semiconductor package 10 according to the first embodiment.

The semiconductor package 10 according to the first embodiment includes a metal base 20, a semiconductor chip 30, at least a molecular bonding layer 40 (refer to FIG. 3), a die bonding adhesive layer 50, lead frames 61, bonding wires 62, and a resin mold 63.

The metal base 20 is an example of a “base.” The “base” referred to herein may be any member to which the semiconductor chip 30 is fixed and may not be made of metal. The “base” may be referred to as a “support.”

The metal base 20 contains metal (i.e., a metal material) 20m having conductivity as a component. The metal 20m is an example of a “first material.” If metal having conductivity is used, the metal base 20 functions as, for example, an electrical ground of the semiconductor package 10. In other words, the semiconductor chip 30 is electrically connected to the metal base 20 (e.g., is connected to the ground) through the die bonding adhesive layer 50. In addition, a material having high thermal conductivity is used for the metal base 20. If a material having high thermal conductivity is used, heat dissipation properties when the semiconductor package 10 is in operation increase. Examples of such a material (i.e., a first material) of the metal base 20 include Cu, Mo, Ag, W, Fe, Ni, and alloys thereof. For example, as a material of the metal base 20, Cu or an alloy of Cu and Mo is preferably used. If such a material is used as a material of the metal base 20, both thermal conductivity and conductivity increase. Also, if the base is made of a non-metal material, the first material may be, for example, a resin (i.e., a synthetic resin), a ceramic, or other materials.

The semiconductor chip (e.g., a bare chip) 30 is a member including, for example, a silicon-containing semiconductor material as a component. The semiconductor chip 30 may be referred to as a “silicon chip.” The semiconductor chip 30 is, for example, a heterojunction field effect transistor (HFET) made of a material such as GaN or SiC or a lateral double diffuse MOS transistor (LDMOS) made of a material such as Si. In addition, as other examples of the semiconductor chip 30, an optical semiconductor element, a piezoelectric element, a memory element, a microcomputer element, a sensor element, and a wireless communication element may be exemplified. The “semiconductor chip (or a semiconductor chip body)” referred to herein may be any component including an electric circuit and is not limited to a specific semiconductor chip. An exemplary material (i.e., a second material) of the semiconductor chip 30 is silicon 30m. Also, a material (i.e., the second material) of the semiconductor chip 30 chemically bonded (e.g., covalently bonded) to the molecular bonding layer 40 may be an insulating material included in an insulating portion on a surface of the semiconductor chip 30. In this case, the “silicon 30m” in the following description may also be understood as an “insulating material.” The “second material” may be the same as or different from the “first material.”

The semiconductor chip 30 includes a first surface 30a and a second surface 30b. On the first surface 30a, conductive pads (i.e., connection portions, electrical connection portions, or terminals) 31 is formed as a part of an electric circuit (refer to FIG. 3). The second surface 30b is positioned on a side opposite to the first surface 30a. The second surface 30b faces the die bonding adhesive layer 50. In the present embodiment, the semiconductor chip 30 has a first region in which a wiring pattern (i,e., a circuit) is formed and a second region which is opposite to the first region and in which no wiring pattern is formed. For example, a wiring pattern is formed on the first surface 30a of the semiconductor chip 30. On the other hand, no wiring pattern is formed on the second surface 30b. The conductive pad 31 of the first surface 30a is a part of a circuit made of a conductive material on a semiconductor substrate. In the present embodiment, the conductive pad 31 is formed by a metal plating of conductive metal on the first surface 30a of the semiconductor chip 30. As the conductive metal, for example, Au, Ni, or Cu is used. For example, the conductive pad 31 has a structure in which a Ni plating layer and an Au plating layer are sequentially laminated on Cu plating serving as a base of the circuit.

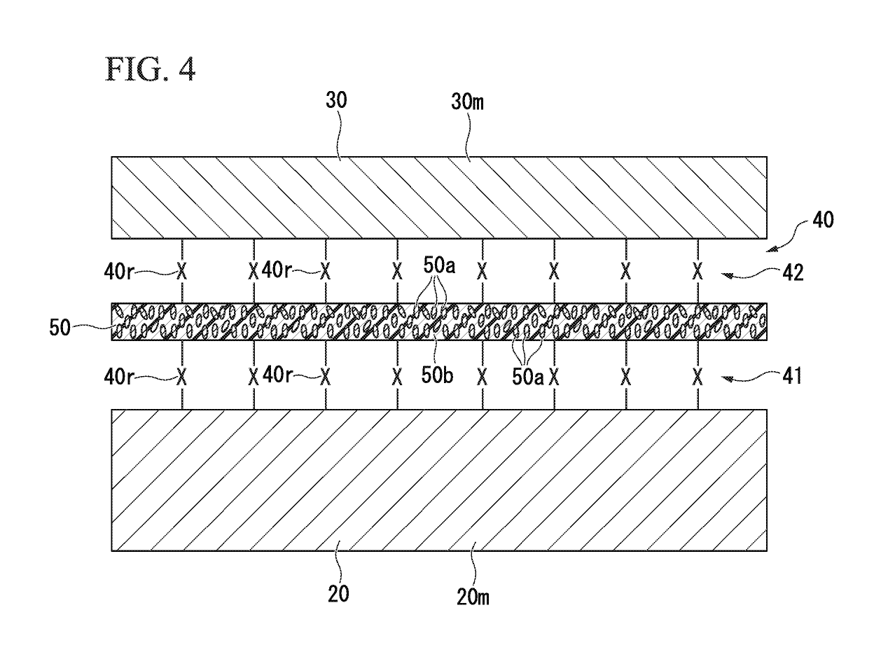

The die bonding adhesive layer 50 is formed between the metal base 20 and the semiconductor chip 30. The die bonding adhesive layer 50 is a connection member that bonds (i.e., joins) the metal base 20 and the semiconductor chip 30 according to, for example, an anchor effect. The die bonding adhesive layer 50 includes a plurality of conductive particles 50a and a resin 50b (refer to FIG. 4). The die bonding adhesive layer 50 has conductivity when the plurality of conductive particles 50a included in the die bonding adhesive layer 50 are in contact with each other and electrically connected each other. In other words, a plurality of conductive particles 50a electrically connects the metal base 20 and the semiconductor chip 30. The conductive particles 50a are particles including a conductive material. The conductive particles 50a may have shapes, for example, ellipsoids, rectangular parallelepipeds, or scaly shapes, but not limited thereto. The conductive material included in the conductive particles 50a can be appropriately selected. For example, metal having high conductivity is used for the conductive particles 50a. As the conductive particles 50a, for example, Ag, Cu, Ni or Au, or a mixed material thereof is used. The conductive particles 50a may be particles made of a conductive material in which the above plurality of types of metal are mixed. For example, the conductive particles 50a may be particles having a plurality of metal layers around each core particle formed of one type of the metal. Diameters of the conductive particles 50a are 2 μm or more as an example, preferably 5 μm or more and 50 μm or less, and more preferably 30 μm or less. For example, the conductive particles 50a may have diameters of 2 μm to 30 μm or 5 μm to 50 μm depending on materials. For example, a content of the conductive particles 50a with respect to a total mass of the die bonding adhesive layer 50 may be 50 to 95 mass %. For example, conductivity of the die bonding adhesive layer 50 in the above ranges is favorable. In the present embodiment, the die bonding adhesive layer 50 is formed of silver paste in which Ag components are used as the conductive particles 50a.

The die bonding adhesive layer 50 is a cured product obtained by a non-cured product in a flexible paste state being supplied between the metal base 20 and the semiconductor chip 30 and then cured. The resin 50b of the die bonding adhesive layer 50 may be appropriately selected, and for example, a resin that contracts during curing may be used. As the resin 50b of the die bonding adhesive layer 50, for example, an acrylic resin, an epoxy resin, a silicone resin, a phenol resin, an imide resin, an amide resin, or an elastomer is used. In the present embodiment, as the resin 50b of the die bonding adhesive layer 50, an epoxy resin is used. In the present embodiment, the die bonding adhesive layer 50 is a cured product obtained by curing a silver paste in which Ag particles serving as the conductive particles 50a are dispersed in the resin 50b. When the semiconductor package 10 is viewed in a plan view (i.e., when viewed in a direction substantially perpendicular to the first surface 30a of the semiconductor chip 30), an area of the die bonding adhesive layer 50 is larger than, for example, an area of the semiconductor chip 30 (e.g., an area of the second surface 30b of the semiconductor chip 30).

In the present embodiment, the metal base 20 and the second surface 30b of the semiconductor chip 30 are electrically connected through the die bonding adhesive layer 50. That is, in the present embodiment, when the metal base 20 and the semiconductor chip 30 are connected with the die bonding adhesive layer 50 disposed therebetween, the metal base 20 and the semiconductor chip 30 are electrically connected through the die bonding adhesive layer 50.

The lead frame (i.e., a connection portion, or an external connection terminal) 61 is an electrical connection terminal for an external member (e.g., a circuit board) with respect to the semiconductor package 10. At least a part of the lead frame 61 protrudes from the resin mold 63.

The bonding wire 62 extends from the conductive pad 31 of the semiconductor chip 30 towards the lead frame 61. The bonding wire 62 is electrically connected the lead frame 61 and the conductive pad 31 of the semiconductor chip 30.

The resin mold (i.e., an insulating portion) 63 covers the metal base 20, the semiconductor chip 30, the die bonding adhesive layer 50, a part of each of the lead frames 61, and the bonding wires 62, and integrally seals these members.

Next, the molecular bonding layer 40 will be described. FIG. 3 is an enlarged cross-sectional view of a vicinity of the semiconductor chip 30. Also, the resin mold 63 is not shown in FIG. 3 for convenience of description.

As shown in FIG. 3, the semiconductor package 10 of the present embodiment includes the molecular bonding layer 40. The molecular bonding layer 40 is formed between the die bonding adhesive layer 50 and at least one of the metal base 20 and the semiconductor chip 30. Although the molecular bonding layer 40 is actually very thin, the molecular bonding layer 40 is depicted with a certain thickness in FIG. 3 for convenience of description.

In the present embodiment, the molecular bonding layer 40 includes a first molecular bonding layer 41 and a second molecular bonding layer 42. The first molecular bonding layer 41 is formed between the metal base 20 and the die bonding adhesive layer 50 and is chemically bonded to both the metal base 20 and the die bonding adhesive layer 50. On the other hand, the second molecular bonding layer 42 is formed between the semiconductor chip 30 and the die bonding adhesive layer 50 and is chemically bonded to both the semiconductor chip 30 and the die bonding adhesive layer 50.

The first molecular bonding layer 41 and the second molecular bonding layer 42 will be described below in detail.

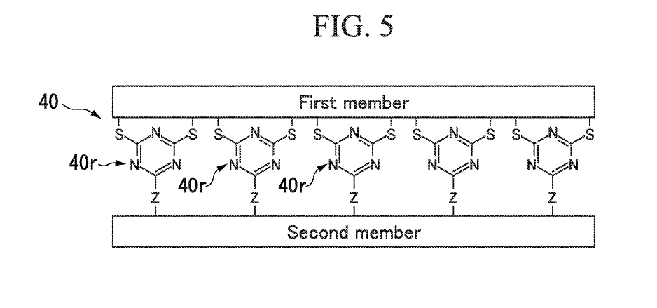

The molecular bonding layer 40 of the present embodiment bonds the die bonding adhesive layer 50 to the metal base 20 and also bonds the die bonding adhesive layer 50 to the semiconductor chip 30. The molecular bonding layer 40 includes molecular bonding systems 40r (refer to FIG. 5) formed by a molecular bonding agent. The molecular bonding agent is a compound capable of forming, for example, a chemical bond (e.g., a covalent bond) with a resin and a metal. The term “covalent bond” herein broadly refers to a bond having a covalent bonding property and includes a coordinate bond, a semi-covalent bond, and the like. In addition, the term “molecular bonding system” herein refers to a substance that remains in a joint part after a molecular bonding agent is chemically bonded (i.e., chemically reacted).

As the molecular bonding agent, for example, a compound such as a triazine derivative may be employed. As the triazine derivative, a compound expressed by the following General Formula (C1) may be employed.

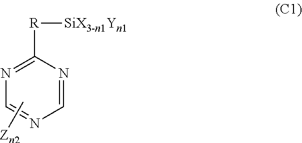

(where, R represents a hydrocarbon group or a hydrocarbon group which may include a hetero atom or a functional group therebetween; X represents a hydrogen atom or a hydrocarbon group; Y represents an alkoxy group; Z represents a thiol group, an amino group or an azido group, which may be a salt, or a hydrocarbon group which may include a hetero atom or a functional group therebetween; n1 represents an integer of 1 to 3; and n2 represents an integer of 1 to 2.)

In General Formula (C1), R is preferably a hydrocarbon group having 1 to 7 carbon atoms or a group having a main chain in which a nitrogen atom is included. X represents a hydrocarbon group having 1 to 3 carbon atoms. Y represents an alkoxy group having 1 to 3 carbon atoms. n1 is preferably 3. n2 is preferably 2. Z preferably represents a thiol group, an amino group or an azido group, which may be a salt, or an alkyl group. As an element for a cation that forms a salt, an alkali metal is preferable. Among alkali metals, Li, Na, K or Cs is more preferable. When n2 is 2, at least one Z is preferably a thiol group, an amino group or an azido group, which is a salt.

At least a part of the first molecular bonding layer 41 (i.e., at least a part of the molecular bonding agent that forms the first molecular bonding layer 41) is chemically bonded (e.g., covalently bonded) to the first material (e.g., the metal 20m) included in the metal base 20. Similarly, a part of the first molecular bonding layer 41 (i.e., at least a part of the molecular bonding agent that forms the first molecular bonding layer 41) is chemically bonded (e.g., covalently bonded) to the resin 50b of the die bonding adhesive layer 50. In addition, a part of the first molecular bonding layer 41 (i.e., at least a part of the molecular bonding agent that forms the first molecular bonding layer 41) is chemically bonded (e.g., covalently bonded) to the conductive particles 50a of the die bonding adhesive layer 50. As a result, the first molecular bonding layer 41 bonds the metal base 20 to the die bonding adhesive layer 50.

FIG. 5 schematically illustrates an example of a composition of the molecular bonding layer 40.

As shown in FIG. 5, the first molecular bonding layer 41 includes, for example, a plurality of molecular bonding systems 40r. The molecular bonding system 40r includes a molecular bonding agent residue that is formed when the above-described molecular bonding agent chemically reacts with bonding targets (a first member and a second member). For example, the molecular bonding system 40r includes a molecular bonding agent residue that is formed when the above-described molecular bonding agent chemically reacts with the metal base 20 and the die bonding adhesive layer 50. The molecular bonding agent residue is, for example, a triazine dithiol residue, as shown in FIG. 5. The molecular bonding system 40r may include “S” or “Z” in FIG. 5. An example of “Z” in FIG. 5 is an amino hydrocarbylsiloxy group.

For example, at least one molecular bonding system 40r included in the first molecular bonding layer 41 is chemically bonded (e.g., covalently bonded) to both the first material (e.g., the metal 20m) of the metal base 20 and the resin 50b of the die bonding adhesive layer 50. In addition, at least one other molecular bonding system 40r included in the first molecular bonding layer 41 is chemically bonded (e.g., covalently bonded) to both the first material (e.g., the metal 20m) of the metal base 20 and the conductive particles 50a of the die bonding adhesive layer 50.

Similarly, at least a part of the second molecular bonding layer 42 (i.e., at least a part of the molecular bonding agent that forms the second molecular bonding layer 42) is chemically bonded (e.g., covalently bonded) to the second material (e.g., the silicon 30m) of the semiconductor chip 30. Similarly, a part of the second molecular bonding layer 42 (i.e., at least a part of the molecular bonding agent that forms the second molecular bonding layer 42) is chemically bonded (e.g., covalently bonded) to the resin 50b of the die bonding adhesive layer 50. In addition, a part of the second molecular bonding layer 42 (i.e., at least a part of the molecular bonding agent that forms the second molecular bonding layer 42) is chemically bonded (e.g., covalently bonded) to the conductive particles 50a of the die bonding adhesive layer 50. Therefore, the second molecular bonding layer 42 joins the semiconductor chip 30 to the die bonding adhesive layer 50.

For example, at least one molecular bonding system 40r included in the second molecular bonding layer 42 is chemically bonded (e.g., covalently bonded) to both the second material (e.g., the silicon 30m) of the semiconductor chip 30 and the resin 50b of the die bonding adhesive layer 50. In addition, at least one other molecular bonding system 40r included in the second molecular bonding layer 42 is chemically bonded (e.g., covalently bonded) to both the second material (e.g., the silicon 30m) of the semiconductor chip 30 and the conductive particles 50a of the die bonding adhesive layer 50.

An adhesion strength between the die bonding adhesive layer 50 and the metal base 20 or between the die bonding adhesive layer 50 and the semiconductor chip 30 is preferably 2 MPa or more, more preferably 5 MPa or more, still more preferably 6 MPa or more, and most preferably 10 MPa or more. In addition, a breaking mode when the adhesion strength is measured is preferably a mode in which the die bonding adhesive layer 50 rather than a bonding interface is broken. The adhesion strength can be measured by, for example, a die shear test. As a specific example of a tensile test, methods defined in MIL-STD883G, IEC-60749-19, EIAJ ED-4703, and the like may be employed.

The molecular bonding agent is chemically bonded (e.g., covalently bonded) to the first material (e.g., the metal 20m) included in the metal base 20 or the second material (e.g., the silicon 30m) included in the semiconductor chip 30 and is chemically bonded (e.g., covalently bonded) to the resin 50b of the die bonding adhesive layer 50, and thus bonds the metal base 20 or the semiconductor chip 30 to the die bonding adhesive layer 50. Since the above-described molecular bonding agent can be chemically bonded (e.g., covalently bonded) to both a metal and a semiconductor, the resin 50b of the die bonding adhesive layer 50 and the metal base 20 or the semiconductor chip 30 can be bonded with a strong adhesive force. In addition, when the molecular bonding agent is chemically bonded (e.g., covalently bonded) to the metal base 20 or the semiconductor chip 30 and the resin 50b of the die bonding adhesive layer 50, a distance between the metal base 20 or the semiconductor chip 30 and the die bonding adhesive layer 50 becomes shorter and an electrical connection between the conductive particles 50a of the die bonding adhesive layer 50 and the metal base 20 or the semiconductor chip 30 is more reliably ensured.

For example, when the first molecular bonding layer 41 formed on a surface of the metal base 20 is chemically bonded (e.g., covalently bonded) to the metal 20m included in the metal base 20 and the resin 50b included in the die bonding adhesive layer 50 and the second molecular bonding layer 42 formed on the surface of the semiconductor chip 30 is chemically bonded (e.g., covalently bonded) to the silicon 30m included in the semiconductor chip 30 and the resin 50b included in the die bonding adhesive layer 50, the metal base 20, the die bonding adhesive layer 50, and the semiconductor chip 30 are electrically and thermally connected to one another by the molecular bonding agent more favorably and electrical and thermal connections between the metal base 20 and the semiconductor chip 30 are ensured more reliably.

In the present embodiment, one molecule (e.g., the molecular bonding system 40r) of the molecular bonding agent in the first molecular bonding layer 41 is chemically bonded (e.g., covalently bonded) to both the resin 50b of the die bonding adhesive layer 50 and the metal 20m of the metal base 20. In addition, one molecule (e.g., the molecular bonding system 40r) of the molecular bonding agent in the second molecular bonding layer 42 is chemically bonded (e.g., covalently bonded) to both the resin 50b of the die bonding adhesive layer 50 and the silicon 30m of the semiconductor chip 30. When the metal 20m of the metal base 20 or the silicon 30m of the semiconductor chip 30 and the resin 50b of the die bonding adhesive layer 50 are bonded via one molecule of the molecular bonding agent, adhesiveness, conductivity, and thermal connectivity further increase. In the present embodiment, one molecule (e.g., the molecular bonding system 40r) of the first molecular bonding layer 41 is chemically bonded (e.g., covalently bonded) to both the conductive particles 50a of the die bonding adhesive layer 50 and the metal 20m of the metal base 20. In addition, one molecule (e.g., the molecular bonding system 40r) of the molecular bonding agent in the second molecular bonding layer 42 is chemically bonded (e.g., covalently bonded) to both the conductive particles 50a of the die bonding adhesive layer 50 and the silicon 30m of the semiconductor chip 30. In such a configuration, stronger electrical and thermal connections between the metal base 20 and the semiconductor chip 30 are ensured. As a result, it is possible to reduce thermal resistance between the metal base 20 and the semiconductor chip 30 and improve a heat dissipation property of the semiconductor chip 30.

Here, if the die bonding adhesive layer 50 becomes thinner, it is possible to reduce thermal resistance between the metal base 20 and the semiconductor chip 30. However, if the die bonding adhesive layer 50 becomes thinner, bonding strength (e.g., a shear strength) of the die bonding adhesive layer 50 with respect to the metal base 20 and the semiconductor chip 30 becomes smaller, and reliability of the semiconductor package 10 may decrease. However, in the present embodiment, since the molecular bonding layer 40 is formed, even if the die bonding adhesive layer 50 is thin, it is possible to maintain a high bonding strength (e.g., a shear strength) of the die bonding adhesive layer 50 with respect to the metal base 20 and the semiconductor chip 30. As a result, it is possible to provide the semiconductor package 10 having a thin die bonding adhesive layer 50 and a desirable heat dissipation property of the semiconductor chip 30. In addition, from a different point of view, when the molecular bonding layer 40 is formed, it is possible to maintain a high proportion of the conductive particles 50a in the die bonding adhesive layer 50 and a high joint strength (e.g., a shear strength) of the die bonding adhesive layer 50 with respect to the metal base 20 and the semiconductor chip 30. As a result, it is possible to increase conductivity (e.g., ground connectivity) and thermal conductivity between the metal base 20 and the semiconductor chip 30.

Each of the first molecular bonding layer 41 and the second molecular bonding layer 42 may have a thickness that is, 0.5 nm or more, preferably 1 nm or more and 20 nm or less.

Here, as shown in FIG. 3, the metal base 20 includes a first region R1 that faces the die bonding adhesive layer 50. In other words, when the metal base 20 is viewed in a plan view, the first region R1 is a region that overlaps the die bonding adhesive layer 50 within the metal base 20. Similarly, the semiconductor chip 30 includes a second region R2 that faces the die bonding adhesive layer 50. In other words, when the semiconductor chip 30 is viewed in a plan view, the second region R2 is a region that overlaps the die bonding adhesive layer 50 within the semiconductor chip 30. In the present embodiment, a coverage ratio of the molecular bonding agent with respect to the first region R1 or the second region R2 is 20% or more and 80% or less. The coverage ratio is preferably 30% or more and 70% or less and more preferably 40% or more and 60% or less. Also, when the coverage ratio of the molecular bonding agent is 100%, it means that the molecular bonding agent is packed theoretically closest with respect to a surface of a target to be covered. The coverage ratio of the molecular bonding agent can be obtained based on results measured by an X-ray diffraction method.

If the coverage ratio of the molecular bonding agent with respect to the first region R1 of the metal base 20 or the second region R2 of the semiconductor chip 30 is the lower limit value or more, it is possible to further increase adhesiveness between the metal base 20 or the semiconductor chip 30 and the die bonding adhesive layer 50. In addition, if the coverage ratio of the molecular bonding agent with respect to the first region R1 of the metal base 20 or the second region R2 of the semiconductor chip 30 is the upper limit value or less, it is possible to ensure an electrical connection and a thermal connection between the metal base 20 or the semiconductor chip 30 and the die bonding adhesive layer 50.

That is, for example, the molecular bonding systems 40r of the molecular bonding layer 40 are not completely uniformly dispersed. The conductive particles 50a of the die bonding adhesive layer 50 are in contact with the metal base 20 or the semiconductor chip 30 at positions (i.e., regions in which the molecular bonding system 40r are not present) between the plurality of molecular bonding systems 40r. Therefore, the conductive particles 50a of the die bonding adhesive layer 50 are electrically connected to the metal base 20 or the semiconductor chip 30.

For example, at least a part of the first molecular bonding layer 41 formed on the surface of the metal base 20 and at least a part of the second molecular bonding layer 42 formed on the surface of the semiconductor chip 30 have a monomolecular film (molecular monolayer) form. That is, the molecular bonding layer 40 consists at least in part of a monomolecular layer. In the present embodiment, the entire first molecular bonding layer 41 and the entire second molecular bonding layer 42 have a monomolecular film form. In a portion that is formed in a monomolecular film form in the first molecular bonding layer 41 or the second molecular bonding layer 42, one molecule of the molecular bonding agent (i.e., the molecular bonding system 40r) is chemically bonded (e.g., covalently bonded) to both the metal 20m of the metal base 20 and the resin 50b of the die bonding adhesive layer 50 or one molecule of the molecular bonding agent (i.e., the molecular bonding system 40r) is chemically bonded (e.g., covalently bonded) to both the silicon 30m of the semiconductor chip 30 and the resin 50b of the die bonding adhesive layer 50. For that reason, it is possible to further increase adhesiveness between the metal base 20 and the semiconductor chip 30, and the die bonding adhesive layer 50. In addition, it is possible to ensure an electrical connection between the metal base 20 and the semiconductor chip 30, and the die bonding adhesive layer 50. Further, an increase in the thickness of the semiconductor package 10 due to the first molecular bonding layer 41 and the second molecular bonding layer 42 can be minimized.

Portions occupying most areas of the first molecular bonding layer 41 and the second molecular bonding layer 42 preferably have monomolecular films. For example, more preferably, within the surfaces of the metal base 20 and the semiconductor chip 30, a portion corresponding to 30 to 100% of an area covered by the first molecular bonding layer 41 and the second molecular bonding layer 42 has a monomolecular film form.

Next, a method of manufacturing the semiconductor package 10 according to the present embodiment will be described.

According to the manufacturing method, for example, at least one of a region in which the die bonding adhesive layer 50 is laminated in the metal base 20 and the second surface 30b of the semiconductor chip 30 is covered with the molecular bonding agent. And, the metal base 20, the die bonding adhesive layer 50, and the semiconductor chip 30 are sequentially laminated, the molecular bonding agent is chemically bonded (e.g., covalently bonded) to the resin 50b of the die bonding adhesive layer 50, and the molecular bonding agent is chemically bonded (e.g., covalently bonded) to at least one of the metal 20m included in the metal base 20 and the silicon 30m included in the semiconductor chip 30.

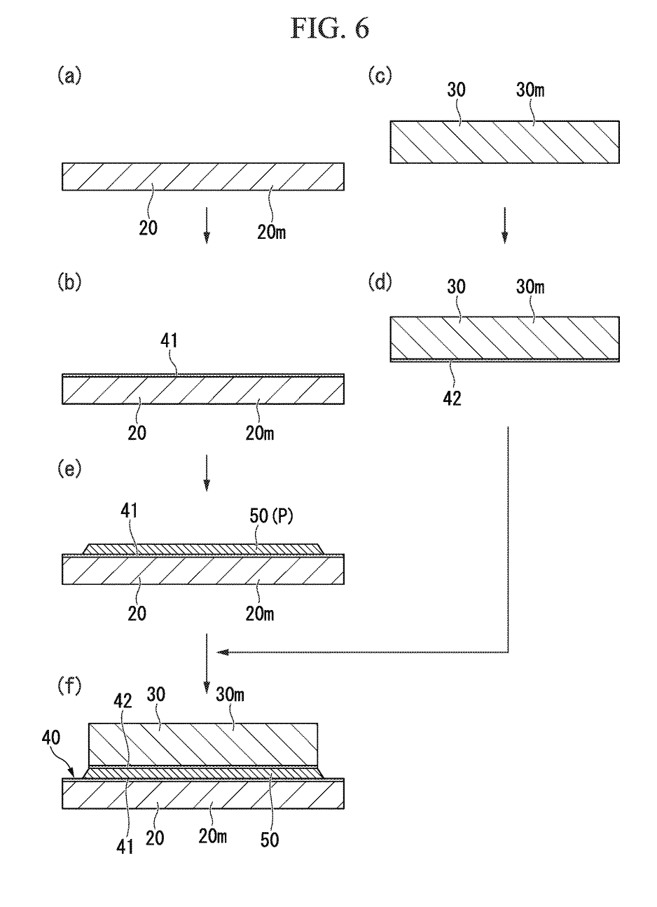

FIG. 6 is a cross-sectional view of a structure in process to show a flow of a method of manufacturing the semiconductor package 10.

In the present embodiment, first, the metal base 20 is prepared ((a) in FIG. 6). Next, by covering a surface of the metal base 20 with the molecular bonding agent (i.e., applying the molecular bonding agent to the surface of the metal base 20), the first molecular bonding layer 41 is formed ((b) in FIG. 6). The “molecular bonding layer” described herein may refer to a molecular bonding layer, at least a part of which has not yet chemically reacted (e.g., has not chemically bonded), or a molecular bonding layer that has chemically reacted (e.g., chemically bonded). The molecular bonding layer, at least a part of which has not yet chemically reacted, may also be understood as a “layer of the molecular bonding agent.”

The first molecular bonding layer 41 is formed by, for example, applying a molecular bonding agent solution including the above-described molecular bonding agent to the metal base 20. The method of applying the molecular bonding agent solution includes a method of immersing the metal base 20 in the molecular bonding agent solution and a method of spraying the molecular bonding agent solution on the metal base 20.

When the surface of the metal base 20 is covered with the molecular bonding agent, the molecular bonding agent solution is preferably used. The molecular bonding agent solution can be prepared by dissolving the above-described molecular bonding agent in a solvent.

Exemplary solvents include alcohols such as methanol, ethanol, isopropanol, ethylene glycol, propylene glycol, cellosolve and carbitol; ketones such as acetone, methyl ethyl ketone and cyclohexanone; aromatic hydrocarbons such as benzene, toluene and xylene; aliphatic hydrocarbons such as hexane, octane, decane, dodecane and octadecane; esters such as ethyl acetate, methyl propionate and methyl phthalate; and ethers such as tetrahydrofuran, ethyl butyl ether and anisole. In addition, a mixture of such solvents can be used.

The concentration of the molecular bonding agent solution is preferably 0.001 mass % or more and 1 mass % or less and more preferably 0.01 mass % or more and 0.1 mass % or less with respect to a total mass of the molecular bonding agent solution. If the concentration of the molecular bonding agent solution is the lower limit value or more, it is possible to further increase the coverage ratio of the molecular bonding agent and adhesiveness between members. If the concentration of the molecular bonding agent solution is the upper limit value or less, since it is difficult to include a molecular bonding agent that does not chemically bond (e.g., covalently bond), it is possible to ensure an electrical connection and a thermal connection between the metal base 20 or the semiconductor chip 30 and the die bonding adhesive layer 50. In addition, it is possible to suppress an increase in thickness of the semiconductor package 10 due to the first molecular bonding layer 41.

The prepared molecular bonding agent solution is applied to the surface of the metal base 20. When the coated metal base 20 is left for a while, chemical bonding (e.g., covalent bonding) between the metal 20m included in the metal base 20 and the molecular bonding agent is promoted. Further, an operation of applying energy (e.g., heat or light (e.g., ultraviolet rays)) to the first molecular bonding layer 41 may be performed. For example, the coated metal base 20 may be heated at a certain temperature for a certain period of time and dried. According to the applied energy, chemical bonding (e.g., covalent bonding) between the metal 20m included in the metal base 20 and the molecular bonding agent is further promoted. Then, when the metal base 20 is cleaned using a cleaning solution and dried, the metal base 20 of which surface is covered with the molecular bonding agent (e.g., the molecular bonding system 40r) is obtained. Also, the cleaning solution may be the same solvent used for the molecular bonding agent solution.

The metal 20m of the metal base 20 covered with the molecular bonding agent forms a chemical bond (e.g., a covalent bond) with the molecular bonding agent (e.g., the molecular bonding systems 40r). That is, the first molecular bonding layer 41 including the molecular bonding agent (e.g., the molecular bonding systems 40r) that is chemically bonded (e.g., covalently bonded) to the metal 20m included in the metal base 20 is formed on the surface of the metal base 20.

The thickness of the first molecular bonding layer 41 can be adjusted according to conditions such as a concentration and an applied amount of the molecular bonding agent solution, a cleaning time, and the number of cleanings.

Similarly, the semiconductor chip 30 is prepared ((c) in FIG. 6). Next, by covering a surface of the semiconductor chip 30 with the molecular bonding agent (i.e., applying the molecular bonding agent to the surface of the semiconductor chip 30), the second molecular bonding layer 42 is formed. In the present embodiment, similarly to the step for forming the metal base 20, the above-described molecular bonding agent solution may be applied to the semiconductor chip 30 and the same operation of leaving, applying energy, and cleaning and drying may be performed. In the present embodiment, through these processes, the silicon 30m included in the semiconductor chip 30 is chemically bonded (e.g., covalently bonded) to the molecular bonding agent. The surface of the semiconductor chip 30 is covered with the molecular bonding agent (e.g., the molecular bonding systems 40r), and the second molecular bonding layer 42 including the molecular bonding agent (e.g., the molecular bonding systems 40r) that is chemically bonded to the silicon 30m included in the semiconductor chip 30 is formed on the surface of the semiconductor chip 30.

Next, the metal base 20, the die bonding adhesive layer 50, and the semiconductor chip 30 are sequentially laminated ((e) and (0 in FIG. 6). For example, first, the die bonding adhesive layer 50 is formed on the metal base 20. As a result, at least a part of the first molecular bonding layer 41 is brought into contact with the resin 50b and the conductive particles 50a of the die bonding adhesive layer 50. Through this process, the resin 50b and the conductive particles 50a of the die bonding adhesive layer 50, and the first molecular bonding layer 41 may be chemically bonded (e.g., covalently bonded).

Next, the semiconductor chip 30 is formed on the die bonding adhesive layer 50. In other words, the die bonding adhesive layer 50 is formed between the metal base 20 and the semiconductor chip 30. As a result, at least a part of the second molecular bonding layer 42 is brought into contact with the resin 50b and the conductive particles 50a of the die bonding adhesive layer 50. Through this process, the resin 50b and the conductive particles 50a of the die bonding adhesive layer 50 and the second molecular bonding layer 42 may be chemically bonded (e.g., covalently bonded).

In the present embodiment, further, an operation of applying energy to the first molecular bonding layer 41 and the second molecular bonding layer 42 is performed. As the energy, for example, heat can be used. When heat is used, heating at about 150 to 200° C. can be performed for 5 minutes or more, preferably 60 minutes or more, more preferably 80 minutes or more, still more preferably 120 minutes or more, and most preferably 240 minutes or less. For example, depending on a material of the molecular bonding layer 40, a period of time between 5 minutes and 120 minutes, preferably 60 minutes and 240 minutes, and more preferably 80 minutes and 240 minutes may be selected. According to such processes, the die bonding adhesive layer 50 is cured and contracts and the die bonding adhesive layer 50 adheres to the metal base 20 and the semiconductor chip 30. Further, chemical bonding (e.g., covalent bonding) between the resin 50b and the conductive particles 50a included in the die bonding adhesive layer 50 and the molecular bonding agent of the first molecular bonding layer 41 is promoted. Further, chemical bonding (e.g., covalent bonding) between the resin 50b and the conductive particles 50a included in the die bonding adhesive layer 50 and the molecular bonding agent of the second molecular bonding layer 42 is promoted. As a result, the molecular bonding agent is chemically bonded (e.g., covalently bonded) to the resin 50b and the conductive particles 50a of the die bonding adhesive layer 50.

As an operation example, paste P including the resin 50b and the conductive particles 50a is placed on the metal base 20 ((e) in FIG. 6). A metal stage of which temperature is set to 150 to 170° C. is prepared and the above-described metal base 20 is placed on the metal stage.

Next, the semiconductor chip 30 is placed on the paste P.

Further, an operation of pressing the semiconductor chip 30 against the metal base 20 while the semiconductor package 10 is heated at a higher temperature and setting the die bonding adhesive layer 50 to have an arbitrary thickness may be performed. For example, the pressing is performed such that the die bonding adhesive layer 50 is pressed from above the semiconductor chip 30 using a pressing member. As conditions for heating to a higher temperature, the metal stage and the pressing member may be heated to a temperature of 180° C. to 200° C. According to this operation, the resin 50b within the paste P that includes the resin 50b and the conductive particles 50a is cured and the die bonding adhesive layer 50 is formed.

According to this operation, further, heat energy is applied to the first molecular bonding layer 41 and the second molecular bonding layer 42 and the resin 50b and the conductive particles 50a of the die bonding adhesive layer 50, and the molecular bonding agent are chemically bonded (e.g., covalently bonded). That is, the resin 50b and the conductive particles 50a included in the die bonding adhesive layer 50 are chemically bonded (e.g., covalently bonded) to the molecular bonding agent included in the first molecular bonding layer 41. The resin 50b and the conductive particles 50a included in the die bonding adhesive layer 50 are chemically bonded (e.g., covalently bonded) to the molecular bonding agent included in the second molecular bonding layer 42. As a result, at least a part of the molecular bonding agent is chemically bonded (e.g., covalently bonded) to the resin 50b and the conductive particles 50a of the die bonding adhesive layer 50, the metal 20m of the metal base 20, and the silicon 30m of the semiconductor chip 30.

Here, chemical bonding (e.g., covalent bonding) of the molecular bonding agent may be performed without applying energy such as heat or light. Alternatively, chemical bonding (e.g., covalent bonding) of the molecular bonding agent may be performed by applying energy such as heat or light.

### Second Embodiment

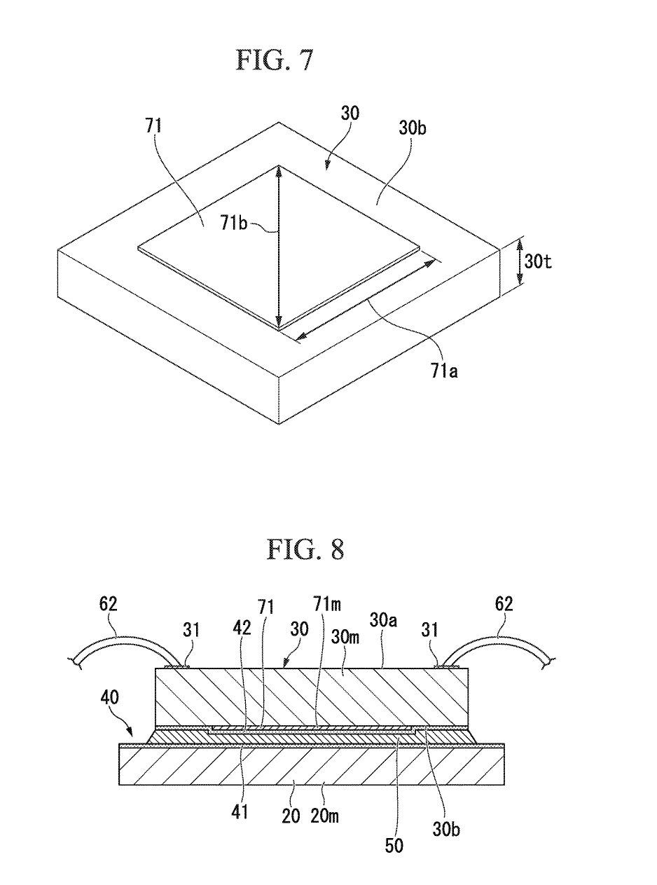

A second embodiment will be described with reference to FIG. 7 and FIG. 8. The second embodiment is different from the first embodiment in that a planar conductor pattern 71 is formed on the semiconductor chip 30. Configurations not described below are the same as those in the first embodiment.

FIG. 7 is a perspective view of the second surface (e.g., a bottom) 30b of the semiconductor chip 30 according to the second embodiment. As shown in FIG. 7, the second surface 30b of the semiconductor chip 30 includes the planar conductor pattern 71. The conductor pattern 71 is, for example, a ground pattern (e.g., a ground pad) that is electrically connected to a ground of the semiconductor chip 30. The conductor pattern 71 is not limited to the ground pattern and may be a power supply pattern (e.g., a power supply pad) or a heat spreader (e.g., a heat dissipation pad).

The shape of the conductor pattern 71 is not particularly limited, and may be a polygonal shape or a circular shape. When the conductor pattern 71 has a polygonal shape, a length of one side 71a (or a diagonal line 71b) of the conductor pattern 71 is, for example, greater than a thickness 30t of the semiconductor chip 30. Similarly, when the conductor pattern 71 has a circular shape, a diameter of the conductor pattern 71 is, for example, greater than the thickness 30t of the semiconductor chip 30. In addition, from another point of view, a length of one side 71a (or the diagonal line 71b, a diameter) of the conductor pattern 71 is greater than half a length of one side of the semiconductor chip 30. Further, from still another point of view, a length of one side 71a (or the diagonal line 71b, a diameter) of the conductor pattern 71 is greater than a sum of widths of two or more conductive pads 31.

In a region adjacent to the relatively large conductor pattern 71 in this manner, water and air are less likely to escape compared to a region adjacent to a resin material or a silicon material. For that reason, in the region adjacent to the relatively large conductor pattern 71, when the semiconductor package 10 is operated (e.g., when heat is generated), the conductor pattern 71 and the die bonding adhesive layer 50 are more likely to be separated from each other. To deal with this issue, in the present embodiment, the molecular bonding layer 40 is formed on a surface of the conductor pattern 71.

FIG. 8 is an enlarged cross-sectional view of a vicinity of the semiconductor chip 30 according to the present embodiment. Also, the resin mold 63 is not shown in FIG. 8 for convenience of description.

As shown in FIG. 8, in the present embodiment, at least a part of the second molecular bonding layer 42 is formed on a surface of the conductor pattern 71 of the semiconductor chip 30. That is, at least a part of the second molecular bonding layer 42 is formed between the conductor pattern 71 of the semiconductor chip 30 and the die bonding adhesive layer 50, and is chemically bonded (e.g., covalently bonded) to both the conductor pattern 71 of the semiconductor chip 30 and the die bonding adhesive layer 50. As a result, the second molecular bonding layer 42 bonds the second conductor pattern 71 of the semiconductor chip 30 to the die bonding adhesive layer 50. For example, at least one molecular bonding system 40r included in the second molecular bonding layer 42 is chemically bonded (e.g., covalently bonded) to both a material 71m included in the conductor pattern 71 of the semiconductor chip 30 and the resin 50b of the die bonding adhesive layer 50. The material 71m is, for example, metal (i.e., a metal material). In addition, at least one other molecular bonding system 40r included in the second molecular bonding layer 42 is chemically bonded (e.g., covalently bonded) to both the conductor pattern 71 of the semiconductor chip 30 and the conductive particles 50a of the die bonding adhesive layer 50. For example, at least one of the molecular bonding systems 40r included in the second molecular bonding layer 42 is chemically bonded (e.g., covalently bonded) to both the material 71m included in the conductor pattern 71 of the semiconductor chip 30 and the conductive particles 50a of the die bonding adhesive layer 50. According to such a configuration, it is possible to suppress separation of the relatively large area conductor pattern 71 and the die bonding adhesive layer 50.

### Third Embodiment

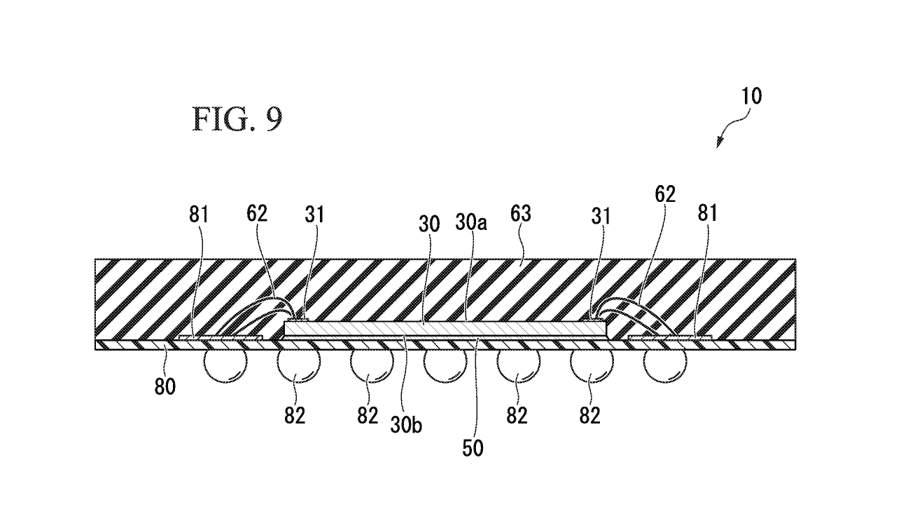

A third embodiment will be described with reference to FIG. 9. The third embodiment is different from the first embodiment in that the semiconductor package 10 includes a board 80 in place of the metal base 20. Configurations not described below are the same as those in the first embodiment.

FIG. 9 is a cross-sectional view of the semiconductor package 10 according to the third embodiment.

As shown in FIG. 9, the semiconductor package 10 includes the board 80, the semiconductor chip 30, the at least one molecular bonding layer 40 (refer to FIG. 3), the die bonding adhesive layer 50, the bonding wires 62, and the resin mold 63.

The board (e.g., an interpose board) 80 is another example of a “base.” A resin (i.e., a synthetic resin) or a ceramic that forms the board 80 is an example of the “first material” included in the board 80. In the present embodiment, the semiconductor chip 30 is mounted on the board 80. The board 80 includes a wiring pattern 81 and a plurality of solder connection portions (i.e., connection portions, electrical connection portions, or external connection terminals, e.g., solder balls) 82 that are electrically connected to the wiring pattern 81. The wiring pattern 81 is electrically connected to the conductive pads 31 of the semiconductor chip 30 via the bonding wires 62.

In the present embodiment, the die bonding adhesive layer 50 is formed between the board 80 and the semiconductor chip 30. For example, the die bonding adhesive layer 50 adheres (i.e., joins) the board 80 and the semiconductor chip 30.

In the present embodiment, similarly to the first embodiment, although not shown in FIG. 9, the molecular bonding layer 40 is formed between the die bonding adhesive layer 50 and at least one of the board 80 and the semiconductor chip 30. For example, the molecular bonding layer 40 includes the first molecular bonding layer 41 and the second molecular bonding layer 42. The first molecular bonding layer 41 is formed between the board 80 and the die bonding adhesive layer 50 and is chemically bonded (e.g., covalently bonded) to both the board 80 and the die bonding adhesive layer 50. The second molecular bonding layer 42 is formed between the semiconductor chip 30 and the die bonding adhesive layer 50 and is chemically bonded (e.g., covalently bonded) to both the semiconductor chip 30 and the die bonding adhesive layer 50.

### Fourth Embodiment

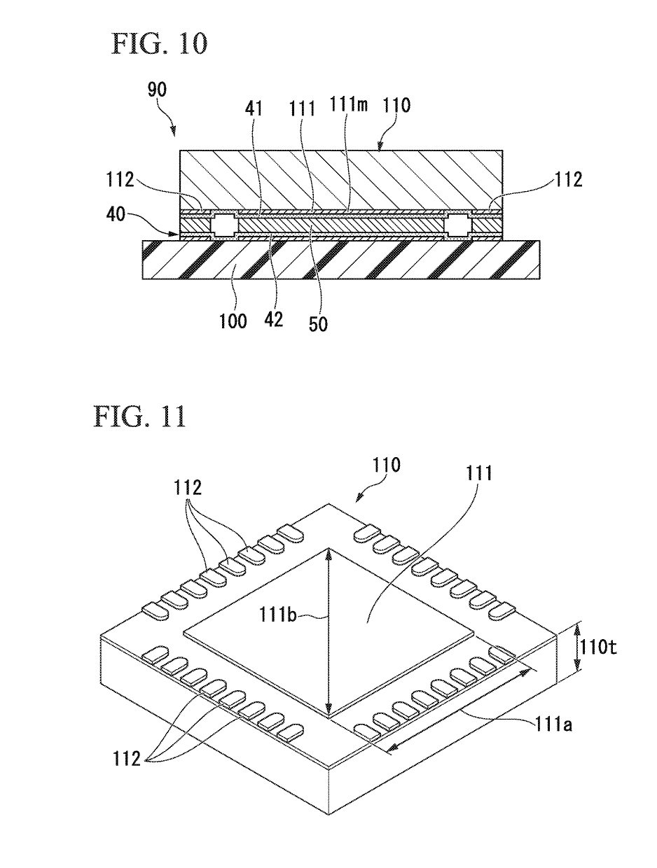

A fourth embodiment will be described with reference to FIG. 10 and FIG. 11. The fourth embodiment is different from the first embodiment in that the molecular bonding layer 40 is formed in a board unit 90. Configurations not described below are the same as those in the first embodiment.

FIG. 10 is a cross-sectional view of the board unit 90 according to the fourth embodiment.

As shown in FIG. 10, the board unit 90 includes a circuit board (e.g., a main board) 100, a semiconductor package (i.e., a semiconductor component) 110, the molecular bonding layer 40, and the die bonding adhesive layer 50. The die bonding adhesive layer 50 is formed between the circuit board 100 and the semiconductor package 110. For example, the die bonding adhesive layer 50 bonds (i.e., joins) the circuit board 100 and the semiconductor package 110.

FIG. 11 is a perspective view of a bottom of the semiconductor package 110 according to the fourth embodiment.

As shown in FIG. 11, the semiconductor package 110 is, for example, a quad flat no-leads package (QFN). Alternatively, the semiconductor package 110 may be a quad flat package (QNP) or other types of semiconductor device. The semiconductor package 110 of the present embodiment includes a planar conductor pattern 111. The conductor pattern 111 is, for example, a ground pattern (e.g., a ground pad) that is electrically connected to a ground of the semiconductor chip 30. The conductor pattern 111 is not limited to the ground pattern and may be a power supply pattern (e.g., a power supply pad) or a heat spreader (e.g., a heat dissipation pad).

The shape of the conductor pattern 111 is not particularly limited, and may be a polygonal shape or a circular shape. When the conductor pattern 111 has a polygonal shape, a length of one side 111a (or a diagonal line 111b) of the conductor pattern 111 is, for example, greater than a thickness 110t of the semiconductor package 110. Similarly, when the conductor pattern 111 has a circular shape, a diameter of the conductor pattern 111 is greater than the thickness 110t of the semiconductor package 110. In addition, from another point of view, one side 111a (or the diagonal line 111b, a diameter) of the conductor pattern 111 is greater than half a length of one side of the semiconductor package 110. Further, from still another point of view, one side 111a (or the diagonal line 111b, a diameter) of the conductor pattern 111 is greater than a sum of widths of two or more conductive pads 112 formed on a surface of the semiconductor package 110.

As shown in FIG. 10, similarly to the first embodiment, according to the fourth embodiment, the molecular bonding layer 40 is formed between the die bonding adhesive layer 50 and at least one of the circuit board 100 and the semiconductor package 110. For example, the molecular bonding layer 40 includes the first molecular bonding layer 41 and the second molecular bonding layer 42. The first molecular bonding layer 41 is formed between the circuit board 100 and the die bonding adhesive layer 50 and is chemically bonded (e.g., covalently bonded) to both the circuit board 100 and the die bonding adhesive layer 50. In addition, the second molecular bonding layer 42 is formed between the semiconductor package 110 and the die bonding adhesive layer 50 and is chemically bonded (e.g., covalently bonded) to both the semiconductor package 110 and the die bonding adhesive layer 50.

At least a part of the second molecular bonding layer 42 is formed on a surface of the conductor pattern 111 of the semiconductor package 110. That is, similarly to the second embodiment, at least a part of the second molecular bonding layer 42 is formed between the conductor pattern 111 of the semiconductor package 110 and the die bonding adhesive layer 50 and is chemically bonded (e.g., covalently bonded) to both the conductor pattern 111 of the semiconductor package 110 and the die bonding adhesive layer 50. For example, at least one of the molecular bonding systems 40r included in the second molecular bonding layer 42 is chemically bonded (e.g., covalently bonded) to both a material him included in the conductor pattern 111 of the semiconductor package 110 and the resin 50b of the die bonding adhesive layer 50. The material him is, for example, metal (i.e., a metal material). In addition, at least one of the molecular bonding systems 40r included in the second molecular bonding layer 42 is chemically bonded (e.g., covalently bonded) to both the material 111m included in the conductor pattern 111 of the semiconductor package 110 and the conductive particles 50a of the die bonding adhesive layer 50. According to such a configuration, it is possible to suppress separation of the relatively large area conductor pattern 111 and the die bonding adhesive layer 50.

According to at least one of the embodiments described above, it is possible to provide a semiconductor package with increased adhesiveness between at least one of a base and a semiconductor chip, and a die bonding adhesive layer by a molecular bonding layer.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a base;
a semiconductor chip on the base;
a conductive bonding layer between a surface of the base and a surface of the semiconductor chip, the conductive bonding layer including a resin and a plurality of conductive particles in the resin; and
a molecular bonding layer between the surface of the semiconductor chip and a surface of the conductive bonding layer, and including a molecular portion covalently bonded to a material of the semiconductor chip and a material of the conductive bonding layer.

2. The semiconductor device according to claim 1, wherein
the molecular bonding layer includes a triazine dithiol residue.

3. The semiconductor device according to claim 1, wherein
a coverage ratio of the molecular bonding layer on a surface of the semiconductor chip is greater than 20% and equal to or smaller than 80%.

4. The semiconductor device according to claim 1, wherein
at least a portion of the molecular bonding layer is a monomolecular layer.

5. The semiconductor device according to claim 1, wherein
the molecular portion is covalently bonded to one of the conductive particles of the plurality of conductive particles.

6. The semiconductor device according to claim 1, wherein
a conductive particle of the plurality of conductive particles comprises at least one of silver, copper, nickel, and gold.

7. The semiconductor device according to claim 1, wherein the base is formed of metal.

8. The semiconductor device according to claim 1, wherein
the semiconductor chip includes a conductive pad on the surface thereof, and
the molecular portion is covalently bonded to a material of the conductive pad.

9. The semiconductor device according to claim 1, wherein
the semiconductor chip includes a plurality of first conductive pads on each edge of the surface thereof, and a second conductive pad in a region of the surface that is surrounded by the first conductive pads, and
the molecular bonding layer includes a second molecular portion covalently bonded to a material of one of the first conductive pads and the material of the conductive bonding layer, and a third molecular portion covalently bonded with a material of the second conductive pads and the material of the conductive bonding layer.

10. The semiconductor device according to claim 1, further comprising:
a second molecular bonding layer between the surface of the base and a surface of the conductive bonding layer that is opposite to the surface on which the molecular bonding layer is disposed, and including a second molecular portion covalently bonded to a material of the base and a material of the conductive bonding layer.

11. The semiconductor device according to claim 1, wherein
the second molecular bonding layer includes a triazine dithiol residue.

12. The semiconductor device according to claim 1, wherein
a coverage ratio of the second molecular bonding layer on a surface of the conductive bonding layer is greater than 20% and equal to or smaller than 80%.

13. The semiconductor device according to claim 1, wherein
at least a portion of the second molecular bonding layer is a monomolecular layer.

14. A semiconductor device comprising:
a base;
a semiconductor chip on the base;
a conductive bonding layer between a surface of the base and a surface of the semiconductor chip, the conductive bonding layer including a resin and a plurality of conductive particles within the resin; and
a molecular bonding layer between the surface of the base and a surface of the conductive bonding layer, and including a molecular portion covalently bonded to a material of the base and a material of the conductive bonding layer.

15. The semiconductor device according to claim 14, wherein
the molecular bonding layer includes a triazine dithiol residue.

16. The semiconductor device according to claim 14, wherein
a coverage ratio of the molecular bonding layer on a surface of the semiconductor chip is greater than 20% and equal to or smaller than 80%.

17. The semiconductor device according to claim 14, wherein
at least a portion of the molecular bonding layer is a monomolecular layer.

18. The semiconductor device according to claim 14, wherein
the molecular portion is covalently bonded to one of the conductive particles of the plurality of conductive particles.

19. The semiconductor device according to claim 14, wherein
a conductive particle of plurality of conductive particles comprises at least one of silver, copper, nickel, and gold.

20. The semiconductor device according to claim 14, wherein the base is formed of metal.
